(19) United States
(12) Patent Application Publication
(10) Pub. No.: US 2010/0025744 A1
(43) Pub. Date: Feb. 4, 2010

(54) SEMICONDUCTOR DEVICE AND METHOD OF MANUFACTURING SAME

(75) Inventors: Toshihiko Miyashita, Tokyo (JP); Keiji Ikeda, Yokohama-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/561,841

(22) Filed: Sep. 17, 2009

Related U.S. Application Data
(63) Continuation of application No. PCT/JP2007/056716, filed on Mar. 28, 2007.

(51) Int. Cl. H01L 29/78; H01L 21/336

(52) U.S. Cl. 257/288; 438/197; 257/E29.255; 257/369; 257/E21.409

(57) ABSTRACT

A semiconductor device includes a gate electrode over a semiconductor substrate, a channel region provided in the semiconductor substrate below the gate electrode, and a strain generation layer configured to apply stress to the channel region, the strain generation layer being configured to apply greater stress in absolute value to the source edge of the channel region than to the drain edge of the channel region.

### CROSS-REFERENCE TO RELATED APPLICATION

The present application is a continuation application filed under 35 U.S.C. 111(a) claiming benefit under 35 U.S.C. 120 and 365(c) of PCT International Application No. PCT/JP2007/056716, filed on Mar. 28, 2007, the entire contents of which are incorporated herein by reference.

### FIELD

A certain aspect of the embodiment discussed herein is related to a semiconductor device and a method of manufacturing the same.

### BACKGROUND

The development of complementary metal oxide semiconductor (CMOS) technologies using silicon (Si) has sustained today's electronics industry. Still now, microfabrication is advancing at a higher pace than ever for further improvement in performance. With respect to the generation of Si CMOS devices represented by a technology node, the mass production of 65 nm node devices has been started, while the focus of development has shifted to 45 nm node devices. Further, the development of the next 32 nm node generation has been started. With this advancement in generations, that is, advancement of microfabrication, the gate length of MOSFETs has been reduced to sizes smaller than half-pitches representing their generations, such as 35 nm (65 nm node) and 25 nm (45 nm node), and is rapidly approaching a physical limit to MOSFET operations.

With such advancement of microfabrication, simple scaling of device dimensions including the gate length alone no longer improves, but rather degrades, not only CMOS device characteristics but also circuit characteristics.

FIG. 1 illustrates changes in circuit characteristics caused by gate length scaling. In theoretical simple scaling that does not consider an increase in OFF current I_{off}, reduction in gate length is supposed to increase current density Iₒₙ so as to reduce delay time, that is, improve circuit speed. As illustrated in FIG. 1, however, in constant I_{off} scaling, the delay time instead increases with a gate length of 40 nm or less. This is believed to be because the ratio of parasitic resistance to the total MOSFET resistance increases to be almost equal in level to channel resistance. This means that the influence of parasitic resistance has become unignorable. It is desired, however, to reduce device size continuously with generations in response to a demand for reduction in chip size while allowing such degradation of characteristics.

Because of these, techniques called “technology boosters” have been introduced as techniques for improving transistor characteristics different from microfabrication at the time of gate length scaling. Among technology boosters, it is the strained-silicon technology that has been developed as the most promising technology. The strained-silicon technology improves the transistor characteristics of the CMOS transistor by improving carrier mobility by applying strain to its channel region. Examples of the method of applying strain to the channel region include providing a stress film coating after formation of a transistor, embedding a substance different in lattice constant from silicon in source and drain regions, and pushing in the channel using the volume expansion of the gate. These methods have been applied to actual products.

The strained-silicon technology has been becoming essential as a low-cost technique for characteristics improvement, and there is a demand for further channel strain for further improvement of CMOS transistor characteristics.

According to the process-induced uniaxial strain technology using a contact etching stop layer (CESL) that has been widely used, increasing the aspect ratio of the gate including sidewall (SW) width is effective for further improvement of channel strain. In order to increase the aspect ratio, the gate height is increased or the sidewall width is reduced.

FIG. 2A is a graph illustrating the dependence of the channel stress applied from a CESL on the poly-gate height in the case of a constant SW width. FIG. 2B is a graph illustrating the dependence of the channel stress applied from a CESL on the SW width in the case of a constant poly-gate height. In the graphs, white circles indicate stress in a channel length direction (hereinafter referred to simply as “channel direction” as required), and triangles indicate stress in a channel width direction perpendicular to the channel length direction. According to FIGS. 2A and 2B, as the poly-gate height increases or the SW width decreases, stress increases particularly in the channel direction so that strain is applied efficiently to the channel. That is, stress may be applied to the channel part with efficiency by increasing the aspect ratio of the gate including the SW width.

For this reason, in order to increase the aspect ratio of the gate, techniques have been developed that shrink (and ultimately omit) sidewalls (SWs). However, the SWs serve as a mask at the time of deep source and drain (SD) impurity implantation, and have the function of controlling a short-channel effect. Accordingly, simply reducing the SW width alone degrades short-channel tolerance, thus making operations difficult under a gate length of 30 nm or less. It may be possible to shrink SWs after SD impurity implantation, but there is concern over damage to implantation layers with this method.

As one of asymmetrical SW configurations of transistors irrelevant to the strained-Si technology, a method is known that manufactures a transistor asymmetrical in SW width by placing a dummy gate electrode next to a desired gate electrode and controlling the distance to the dummy gate electrode. (See, for example, Japanese Laid-open Patent Publication No. 2002-190589.) According to this method, a decrease in current due to parasitic resistance is prevented by reducing the width of the source-side low concentration impurity diffusion region by reducing the SW width on the source side, and hot carrier tolerance is improved by reducing an electric field in the drain-side low concentration impurity diffusion region.

Further, also known are an offset spacer structure where only the drain-side SW of a gate electrode has a double structure (for example, Japanese Laid-open Patent Publication No. 2005-268620) and an asymmetrical SW structure where the drain-side SW is made thicker by forming a gate electrode so that the gate electrode has an asymmetrical cross-sectional shape like a yacht sail in the channel direction (for example, Japanese Laid-open Patent Publication No. 8-153877). The short-channel effect may be controlled by these structures.

### SUMMARY

According to an aspect of the present invention, a semiconductor device includes a gate electrode over a semiconductor substrate; a channel region provided in the semiconductor substrate below the gate electrode; and a strain generation layer configured to apply stress to the channel region, the strain generation layer being configured to apply greater stress in absolute value to a source edge of the channel region than to a drain edge of the channel region.

According to an aspect of the present invention, a method of manufacturing a semiconductor device includes forming a gate electrode on a semiconductor substrate; forming a first sidewall spacer and a second sidewall spacer on a first side and a second side, respectively, of the gate electrode; implanting an impurity into one of the first sidewall spacer and the second sidewall spacer so as to cause a wet etching rate to differ between the first sidewall spacer and the second sidewall spacer; and etching the first sidewall spacer and the second sidewall spacer after said implanting.

The object and advantages of the embodiment will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF THE DRAWING(S)

FIG. 1 is a graph illustrating degradation of circuit characteristics caused by gate length scaling;

FIGS. 2A and 2B are graphs illustrating a simulated increase in stress in the channel directions caused by an increase in the aspect ratio of a gate;

FIG. 3 is a schematic cross-sectional view of a semiconductor device according to an embodiment;

FIG. 4 is a graph illustrating a simulation result illustrating a distribution of stress applied to the channel region of a PMOSFET having a CESL that applies compressive stress according to the embodiment;

FIG. 5 is a diagram for illustrating the effect of applying strain to a source edge according to the embodiment;

FIG. 6 is a schematic cross-sectional view of a variation of the semiconductor device according to the embodiment;

FIG. 7 is a schematic cross-sectional view of another variation of the semiconductor device according to the embodiment;

FIG. 8 is a schematic cross-sectional view of yet another variation of the semiconductor device according to the embodiment;

FIGS. 9A through 9H are diagrams illustrating a semiconductor device manufacturing process according to the embodiment; and

FIGS. 10A through 10H are diagrams illustrating a variation of the semiconductor device manufacturing process according to the embodiment.

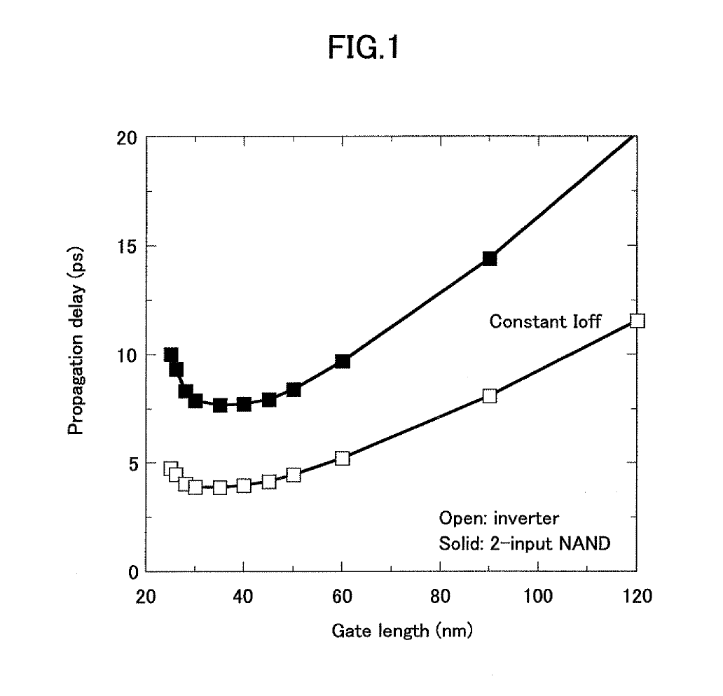

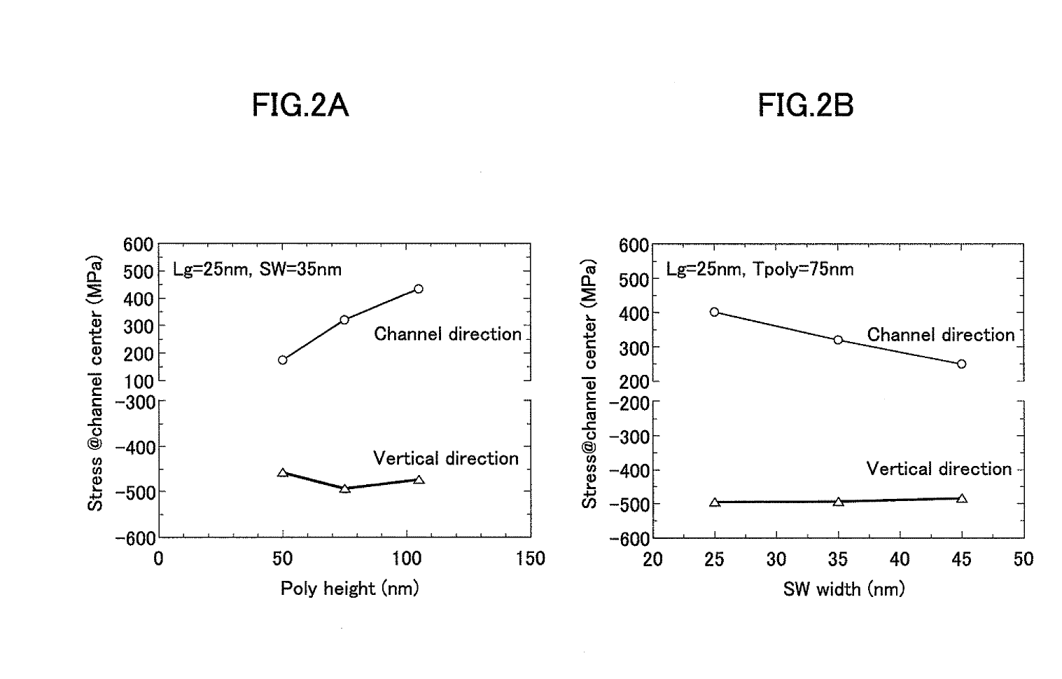

### DESCRIPTION OF EMBODIMENT

Although the short-channel effect may be controlled by the above-described structure, none of the above-described documents is relevant to the strained-Si technology, and deals with the SW asymmetry in relation to the stress applied to a channel.

Further, while introduction of stress techniques is desired in advancing the scaling of CMOS devices, ballistic transport, by which carriers running through a channel are never subjected to scattering before reaching a drain from a source, is dominant where the gate length is less than 30 nm. In ballistic conduction, mobility improvement techniques based on channel strain are no longer significant to carriers running through a channel, and the thermal injection velocity of carriers at a source edge is decisive.

The inventors have found it desirable to apply channel strain intensively to a source edge in order to improve the characteristics of microfabricated semiconductor devices, particularly devices in the ballistic conduction range where the gate length is 30 nm or less.

According to an aspect of the present invention, there are provided a device structure for improving transistor characteristics even in micro CMOS devices with advanced scaling by applying strained-Si techniques in the 45 nm node and subsequent generations, particularly by efficiently applying strain from a CESL to a channel, and a process for manufacturing the device structure.

According to an aspect of the present invention, characteristics are improved efficiently by channel strain and the short-channel effect is controlled to enable switching under a gate length of 30 nm or less in high-performance logic devices having a gate length of 30 nm or less.

A preferred embodiment of the present invention is explained below with reference to accompanying drawings.

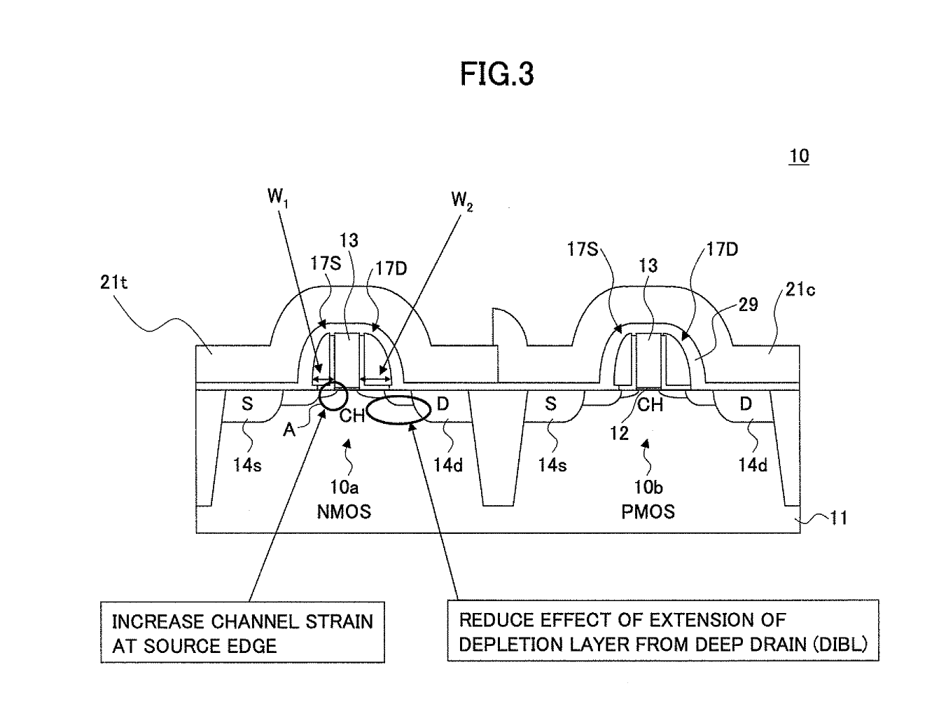

FIG. 3 is a schematic cross-sectional view of a semiconductor device 10 according to the embodiment of the present invention. In the case illustrated in FIG. 3, a CMOS (complementary metal-oxide semiconductor) device including an NMOSFET (n-channel MOS field-effect transistor) 10a and a PMOSFET (p-channel MOS field-effect transistor) 10b is provided on a semiconductor substrate 11.

Each of the MOSFETs 10a and 10b includes a gate electrode 13 formed over the semiconductor substrate 11 with a gate insulating film 12 interposed between them; a channel region CH extending in a region immediately below the gate electrode 13 in the semiconductor substrate 11; and a source region 14s and a drain region 14d extending on the corresponding sides of the channel region CH. Sidewall (SW) spacers 17S and 17D are provided on the source side and the drain side, respectively, of the gate electrode 13. The sidewall spacer 17S has a width W₁, which is narrower (smaller) than a width W₂ of the sidewall spacer 17D.

The NMOSFET 10a and the PMOSFET 10b are covered with contact etch stop layers (CESLs) 21t and 21c, respectively, with a protection film 29 interposed between the NMOSFET and PMOSFET 10b and 10c and the CESLs 21t and 21c. The CESLs 21t and 21c serve as etching stoppers and also as strain generation layers. The CESL 21t over the NMOSFET 10a applies tensile strain in the channel length directions and compressive strain in the channel depth directions to the channel region CH of the NMOSFET 10a. In this sense, the CESL 21t is referred to as “tensile CESL.” On the other hand, the CESL 21c over the PMOSFET 10b applies compressive strain in the channel length directions and tensile strain in the channel depth directions to the channel region CH of the PMOSFET 10b. In this sense, the CESL 21c is referred to as “compressive CESL.”

As described above, in the CMOSFET of FIG. 3, the sidewall width is smaller on the source side than on the drain side of the gate electrode 13 in each of the NMOSFET 10a and the PMOSFET 10b. Generally, as the length of a gate is shrunk, the short-channel effect, or reduction in threshold voltage due to reduced contribution of the gate to a channel electric field by the extension of a depletion layer from a drain region, particularly, by the effect of an electric field from a deep drain, becomes a problem. In order to control this short-channel effect as much as possible, it is effective to move a deep diffusion region on the drain side as far away from a channel end (edge) as possible, that is, to maximize the sidewall width.

On the other hand, however, in the case of using a process-induced uniaxial strain technique as in the case of FIG. 3, it is possible to obtain large strain (or stress) at a sidewall end (edge) in particular, so that it is desirable to minimize the sidewall width in order to improve characteristics by improving mobility by strain.

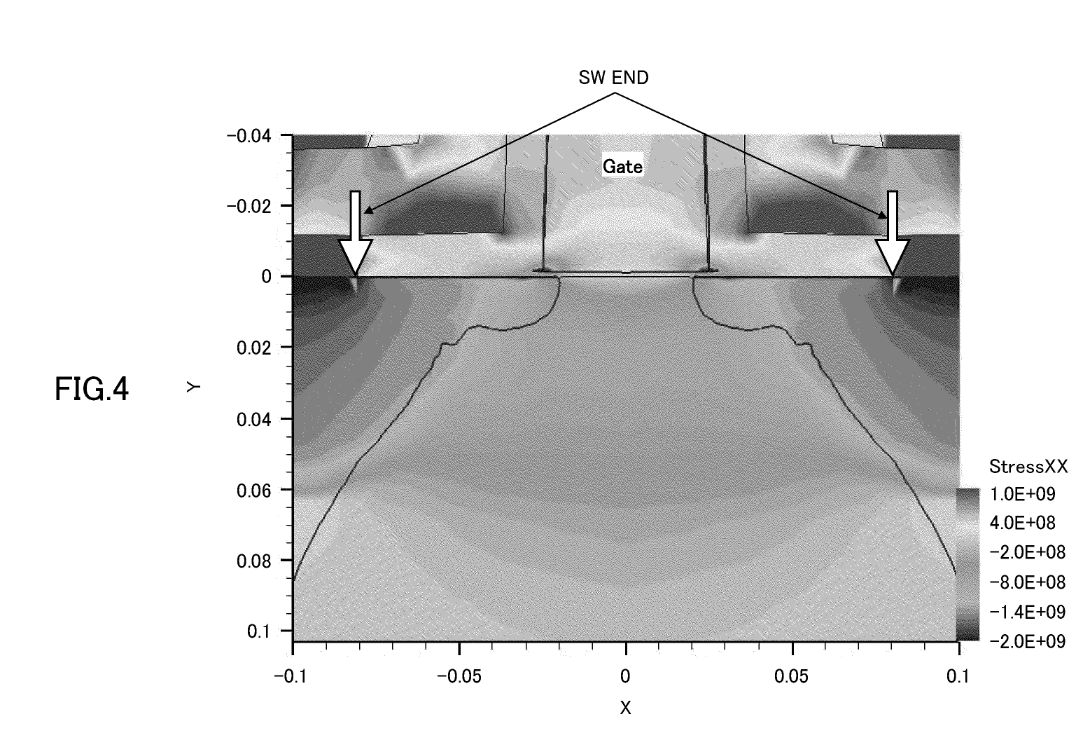

FIG. 4 is a graph illustrating the result of calculation by a two-dimensional simulation of a stress distribution in the channel region CH of the PMOSFET 10b covered with the CESL 21c that generates compressive stress. It is seen from FIG. 4 that, as indicated by arrows, the stress in the channel directions (X directions) increases toward sidewall ends and attenuates toward the channel center.

On the other hand, when the gate length is reduced by microfabrication so as to result in a ballistic transport where carriers injected from a source reach a drain without being ever scattered through a channel, a completely diffusive carrier injection velocity that exceeds a source potential becomes a bottleneck in the carrier transport, and it is desirable to increase the carrier injection velocity to improve device characteristics.

This is schematically illustrated in FIG. 5. Device characteristics may be improved by increasing an injection velocity Vᵢₙⱼ at which carriers are injected from a source region into a channel region CH beyond a potential barrier. That is, this means that it is unnecessary to apply strain evenly to the channel and that strain may be applied efficiently at a source edge A (a circled region in FIG. 3).

Therefore, referring back to FIG. 3, the drain-side sidewall spacer 17D has the larger width W₂ in order to suppress the extension of a depletion layer from the drain region 14d (drain-side deep diffusion region) as indicated by an ellipse in FIG. 3, while the source-side sidewall spacer 17S has the smaller width W₁ in order to increase strain at the source edge A in the channel region CH in each of the NMOSFET 10a and the PMOSFET 10b. Such an asymmetrical SW structure under strained-silicon may be referred to as an ideal CMOSFET structure in and after the 45 nm node generation.

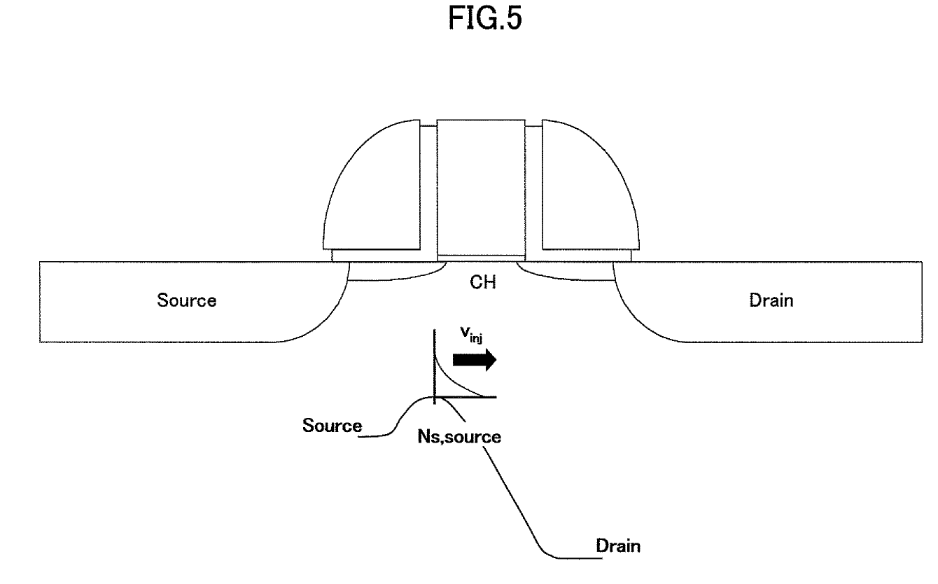

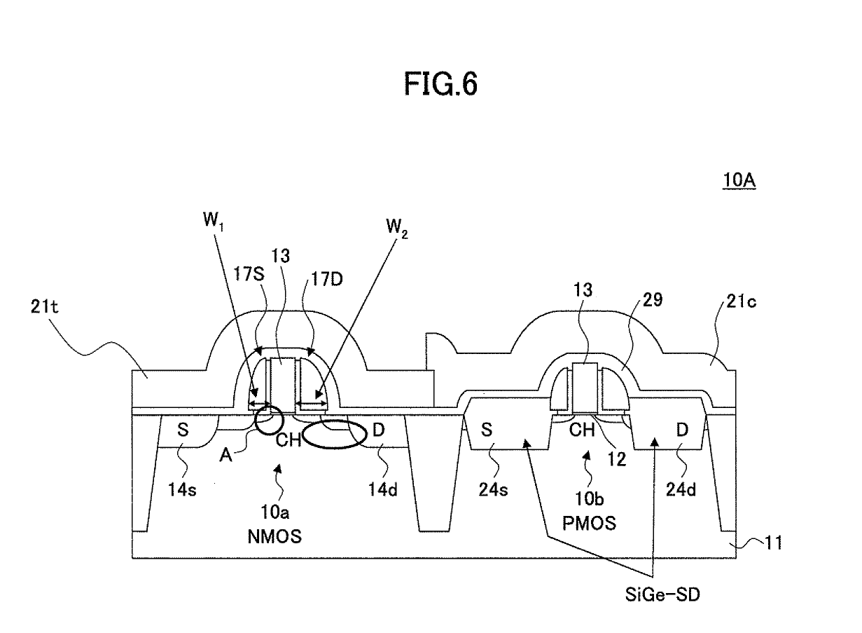

FIG. 6 is a diagram illustrating a variation of the semiconductor device 10 of FIG. 3. Referring to FIG. 6, a semiconductor device 10A employs an embedded compound semiconductor structure. For example, the semiconductor device 10A employs an embedded-Si₁₋ₓGeₓ (0<x<0.3) structure where Si₁₋ₓGeₓ (0<x<0.3), which is a strain generation layer, is embedded in the source region and the drain region of the PMOSFET 10b to form a SiGe source layer (region) 24s and a Si₁₋ₓGeₓ (0<x<0.3) drain layer (region) 24d, so as to further improve the characteristics of the PMOSFET 10b.

The Si₁₋ₓGeₓ (0<x<0.3) source layer 24s and the Si₁₋ₓGeₓ (0<x<0.3) drain layer 24d apply uniaxial compressive stress to the P-channel region CH so as to provide the P-channel region CH with strain. By using the Si₁₋ₓGeₓ (0<x<0.3) source and drain layers 24s and 24d and the compressive CESL layer 21c together, carrier mobility in the PMOSFET 10b is further improved. In this case also, strain is applied more efficiently at the source edge A in the channel region CH by causing the width W₁ of the source-side sidewall spacer 17S to be smaller than the width W₂ of the drain-side sidewall spacer 17D in each of the NMOSFET 10a and the PMOSFET 10b.

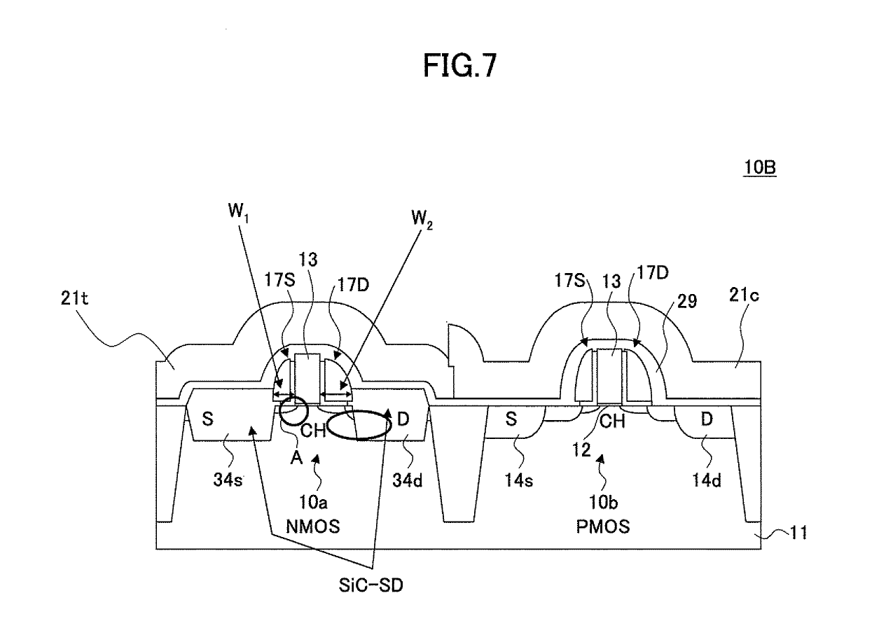

FIG. 7 is a diagram illustrating another variation of the semiconductor device 10 of FIG. 3. Referring to FIG. 7, a semiconductor device 10B employs an embedded compound semiconductor structure. For example, the semiconductor device 10B employs an embedded-Si_{1-y}C_{y} (0<y<0.05) structure where Si_{1-y}C_{y} (0<y<0.05), which is a strain generation layer, is embedded in the source region and the drain region of the NMOSFET 10a to form a Si_{1-y}C_{y} (0<y<0.05) source layer 34s and a Si_{1-y}C_{y} (0<y<0.05) drain layer 34d, so as to further improve the characteristics of the NMOSFET 10a.

The Si_{1-y}C_{y} (0<y<0.05) source layer 34s and the Si_{1-y}C_{y} (0<y<0.05) drain layer 34d apply tensile stress to the N-channel region CH. By using the Si_{1-y}C_{y} (0<y<0.05) source and drain layers 34s and 34d and the tensile CESL layer 21t together, the characteristics of the NMOSFET 10a are further improved. Further, strain is applied more efficiently at the source edge A in the channel region CH by causing the width W₁ of the source-side sidewall spacer 17S to be smaller than the width W₂ of the drain-side sidewall spacer 17D in each of the NMOSFET 10a and the PMOSFET 10b.

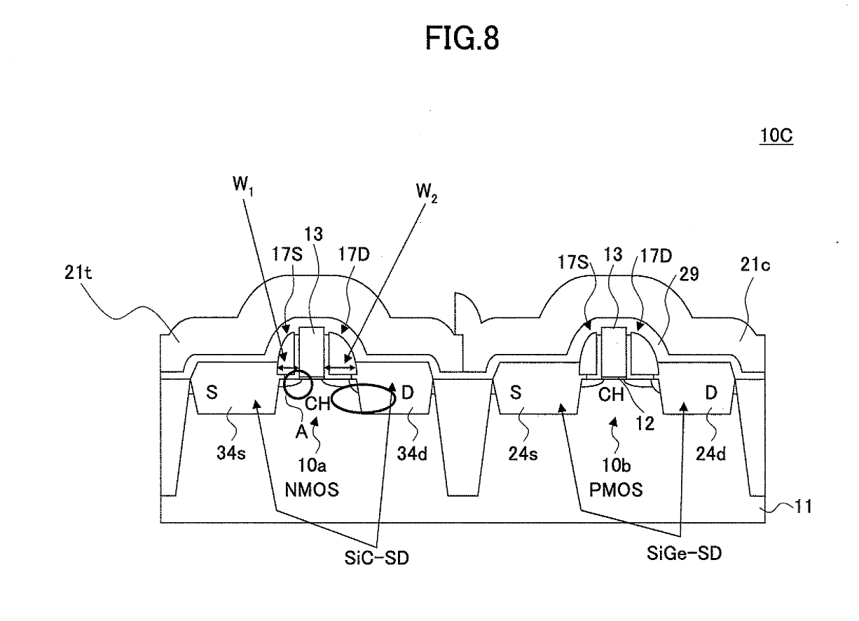

FIG. 8 is a diagram illustrating yet another variation of the semiconductor device 10 of FIG. 3. Referring to FIG. 8, in order to further improve the characteristics of both NMOSFET 10a and PMOSFET 10b, a semiconductor device 10C embeds Si_{1-y}C_{y} (0<y<0.05), which applies tensile stress, in the source region and the drain region of the NMOSFET 10a to form the Si_{1-y}C_{y} (0<y<0.05) source layer 34s and the Si_{1-y}C_{y} (0<y<0.05) drain layer 34d, and embeds Si₁₋ₓGeₓ (0<x<0.3), which applies compressive stress, in the source region and the drain region of the PMOSFET 10b to form the Si₁₋ₓGeₓ (0<x<0.3) source layer 24s and the Si₁₋ₓGeₓ (0<x<0.3) drain layer 24d. Strain is applied more efficiently at the source edge A in the channel region CH by causing the width W₁ of the source-side sidewall spacer 17S to be smaller than the width W₂ of the drain-side sidewall spacer 17D in each of the NMOSFET 10a and the PMOSFET 10b.

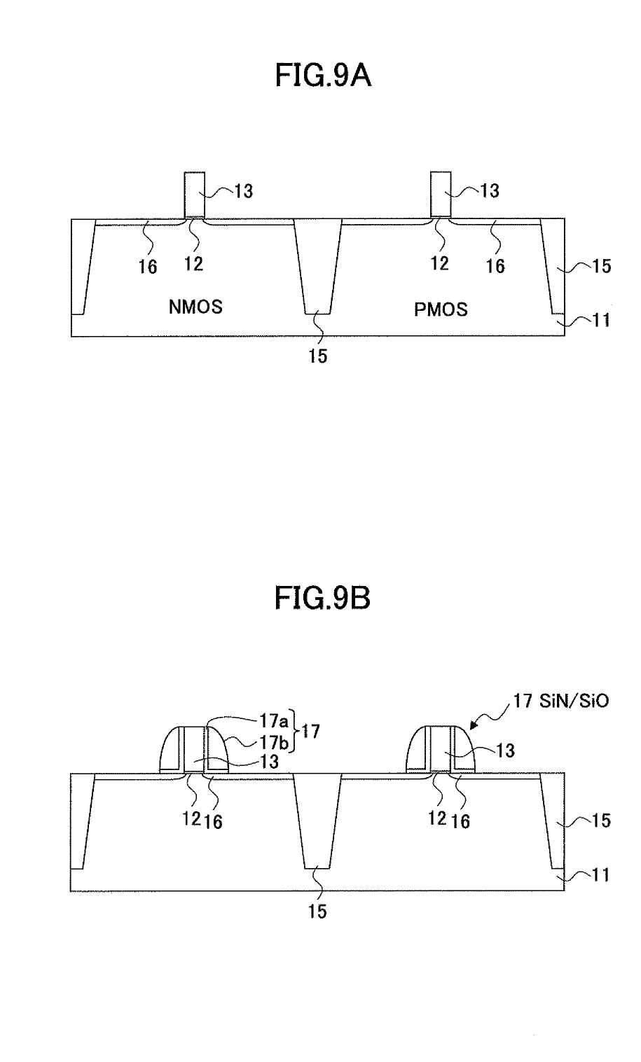

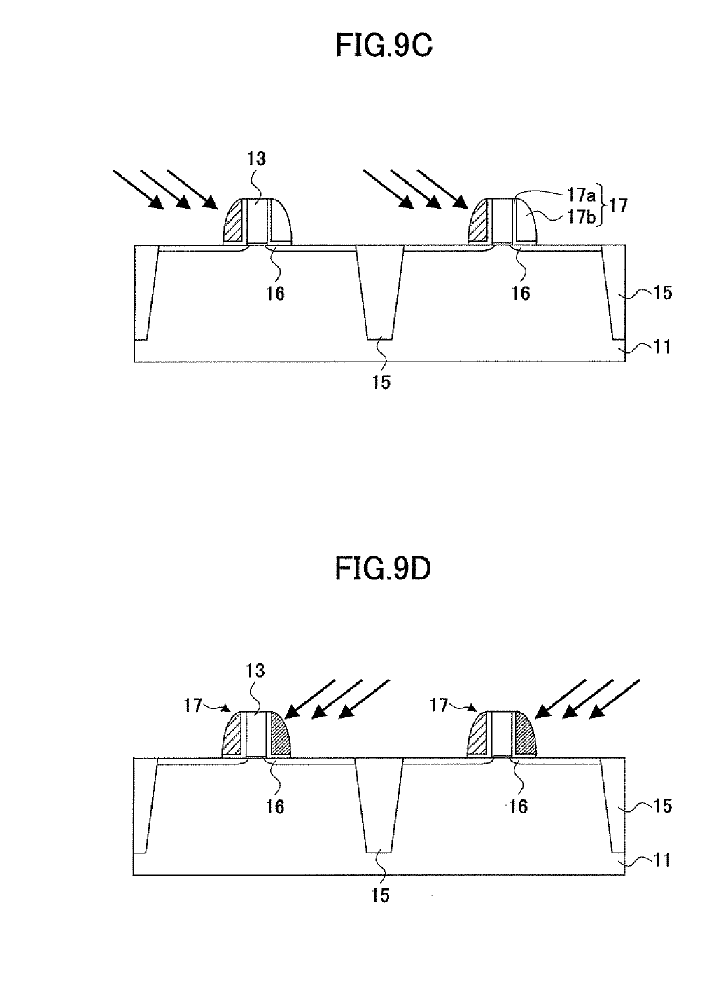

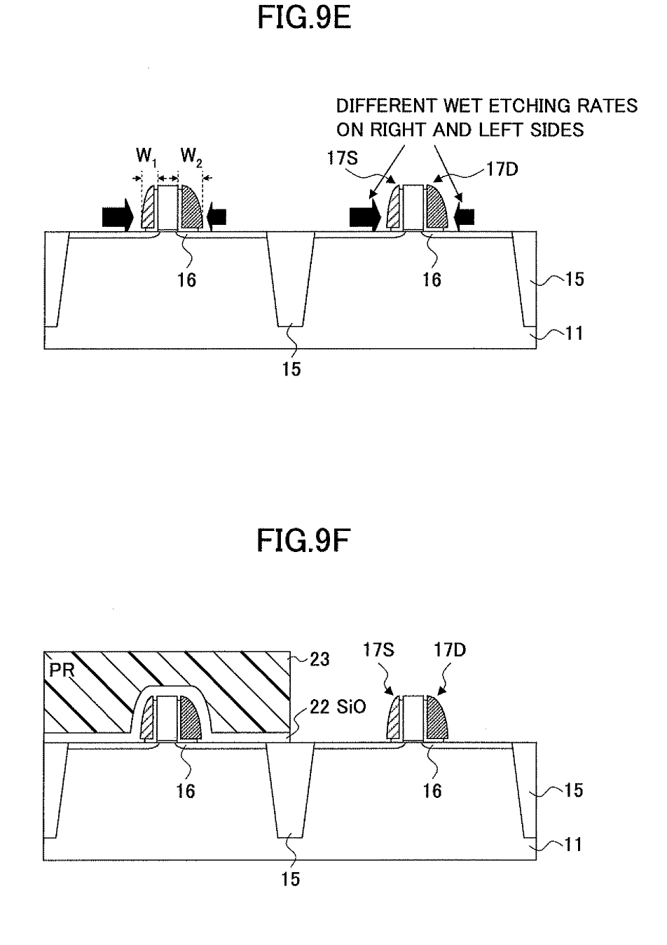

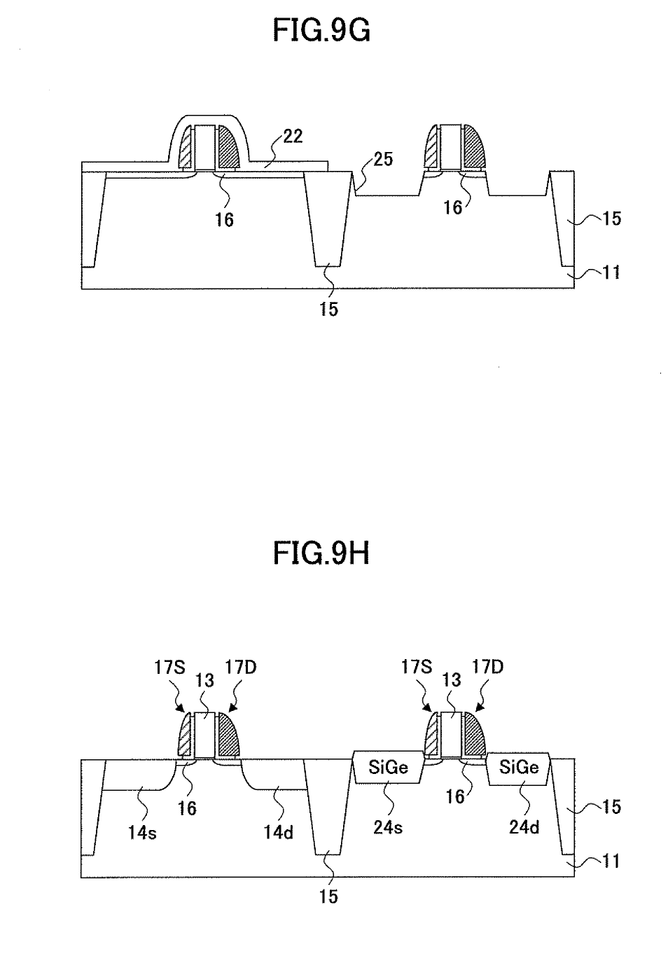

FIGS. 9A through 9H are diagrams illustrating a process for manufacturing the semiconductor device 10A of FIG. 6.

First, as illustrated in FIG. 9A, isolation regions 15 such as shallow trench isolations (STIs) are formed at predetermined positions in the silicon substrate 11. A well of a predetermined conduction type (not graphically illustrated) is formed in a predetermined region of the silicon substrate 11, and channel impurities (not graphically illustrated) are introduced. Thereafter, the surface of the silicon substrate 11 is cleaned, and a gate insulating material film and a polysilicon film are deposited on the surface. For example, the gate electrodes 13 of 18 nm to 30 nm in line width are formed on the corresponding gate insulating films 12 by excimer laser lithography using an ultra-high resolution technology and reactive ion etching (RIE). Source and drain extension regions 16 of each of the NMOSFET 10a and the PMOSFET 10b are formed using the gate electrodes 13 as masks.

The source and drain extension regions of the NMOSFET 10a are formed by, for example, ion implantation of As⁺ ions with a dose of 1E15 cm⁻² at 2 keV, and pocket impurity implantation of B⁺ ions with a dose of 1E13 cm⁻² at 10 keV at a tilt angle of 30° in four directions. The source and drain extension regions of the PMOSFET 10b are formed by, for example, ion implantation of B⁺ ions with a dose of 1E15 cm⁻² at 0.5 keV, and pocket impurity implantation of As⁺ ions with a dose of 5E12 cm⁻² at 40 keV at a tilt angle of 30° in four directions.

Next, as illustrated in FIG. 9B, a silicon oxide (SiO₂) film 17a of approximately 10 nm in thickness and then a silicon nitride (SiN) film 17b of approximately 50 nm in thickness are deposited by CVD at a film formation temperature of 600° C. or less. Thereafter, the entire surface is etched back by RIE so as to leave sidewalls 17 one on each side of each gate electrode 13. Each sidewall 17 includes the SiO₂ film 17a and SiN film 17b to have a SiN/SiO structure. Consideration is given to the width of the sidewalls 17 at this stage so as to prevent deep source and drain implantation from affecting a short-channel effect.

Next, as illustrated in FIG. 9C, such ions as to increase a wet etching rate for the SiN films (SiN film sidewalls) 17b are implanted into the gates, whose directions are made uniform (unified into a single direction) in a circuit, unidirectionally from the source side. In this case, P⁺ ions are implanted with a dose of 5E14 cm⁻² at 3 keV at a tilt angle of 30° to 60° (unidirectional tilt implantation of P⁺ ions).

Further, as illustrated in FIG. 9D, such ions as to decrease the wet etching rate for the SiN films (SiN film sidewalls) 17b are implanted into the gates unidirectionally from the drain side. In this case, B⁺ ions are implanted with a dose of 5E14 cm⁻² at 1 keV at a tilt angle of 30° to 60° (unidirectional tilt implantation of B⁺ ions).

The ion implantations of FIG. 9C and FIG. 9D are performed unidirectionally (from a single direction) at a high tilt angle of 30° or more (≦60°) relative to the gate electrodes 13. Therefore, in each ion implantation, an impurity is implanted selectively into the sidewall 17 on one side of each gate electrode 13. Further, the implantation energy and the implantation dose are set to such conditions as to exert no influence over the short channel effect of the MOSFETs 10a and 10b and cause the wet etching rate to differ sufficiently between the SiN films 17b on different sides. Further, if desired, spike RTA (rapid thermal annealing) of, for example, 1000° C. or less and 0 s is performed after the implantations (LDD annealing). This annealing may also enhance the difference in wet etching rate between the selectively ion-implanted sidewalls 17 on different sides.

Next, as illustrated in FIG. 9E, wet etching with phosphoric acid (H₃PO₄) is performed on the structure of FIG. 9D. As a result, since the etching rate with respect to phosphoric acid differs between the source-side and drain-side sidewalls 17, etching progresses more on the source side, so that laterally asymmetrical sidewall width is realized. That is, the source-side and drain-side sidewall spacers 17S and 17D are formed. Here, letting the source-side sidewall width and the drain-side sidewall width be W₁ and W₂, respectively, W₁ is smaller than W₂ (W₁<W₂).

It is also possible to perform only one of the source-side ion implantation of FIG. 9C for promoting wet etching and the drain-side ion implantation of FIG. 9D for slowing down wet etching. This is because since implanting ions into only one of the source-side and drain-side sidewalls 17 still makes a difference in wet etching rate between the source-side and drain-side sidewalls 17, the asymmetrical sidewall shape is formed by the wet etching process of FIG. 9E.

Next, in the process of FIG. 9F, a cap oxide film 22 such as a SiO film is deposited on the structure of FIG. 9E, and a resist mask 23 such as a photoresist mask having an opening pattern on the PMOS region is formed by photolithography. Then, the surface of the substrate 11 in the PMOS region is exposed by removing the cap oxide film 22 by processing such as RIE.

Next, as illustrated in FIG. 9G, grooves 25 are formed in the source and drain regions of the PMOS region by dry etching, and the resist mask 23 is removed.

Next, as illustrated in FIG. 9H, Si₁₋ₓGeₓ (0<x<0.3) doped with, for example, B is caused to grow epitaxially selectively in the grooves 25 of the PMOS region, so that the Si₁₋ₓGeₓ (0<x<0.3) source layer 24s (strain source) and the Si₁₋ₓGeₓ (0<x<0.3) drain layer 24d (strain drain) are formed. Thereafter, the cap oxide film 22 (SiO mask) in the NMOS region is removed. Then, the PMOS region is covered with a mask (not graphically illustrated), and a source and drain impurity is implanted deep in the substrate 11 in the NMOS region. Thereafter, the impurity is activated by RTA to form the deep source and drain regions 14d and 14s, and the mask on the PMOS region is removed. Thereafter, although not graphically illustrated, the surfaces of the gate electrodes 13, the source and drain regions 14s and 14d, and the Si₁₋ₓGeₓ (0<x<0.3) source and drain layers 24s and 24d are silicided, and the protection film 29 (FIG. 6) and the CESLs 21t and 21c (FIG. 6) are formed. As a result, the semiconductor device 10A as illustrated in FIG. 6 is manufactured.

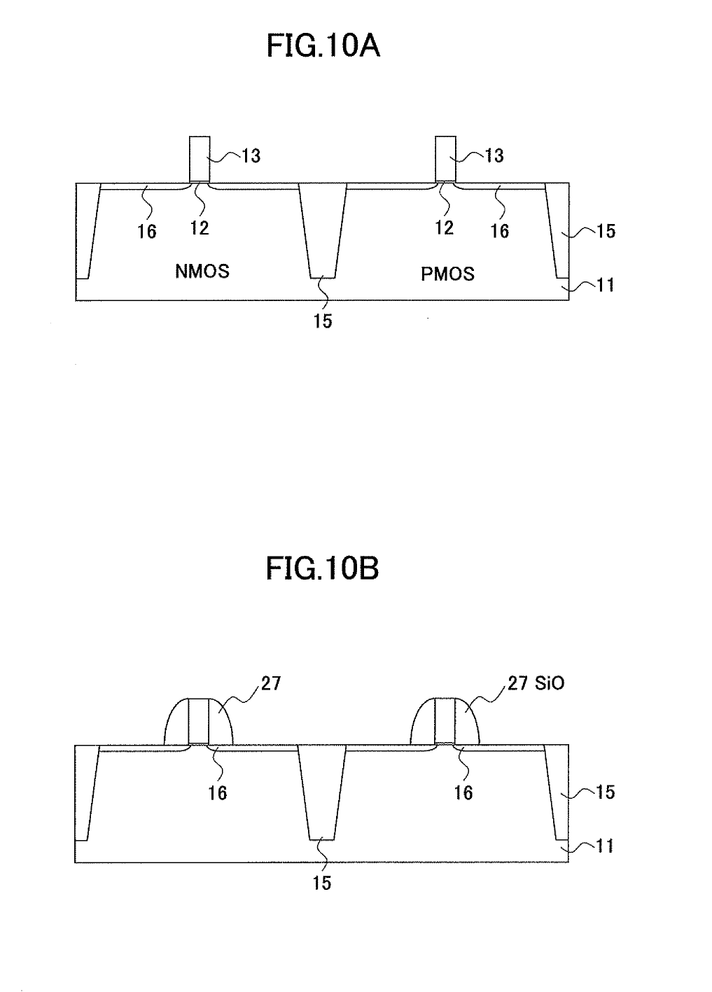

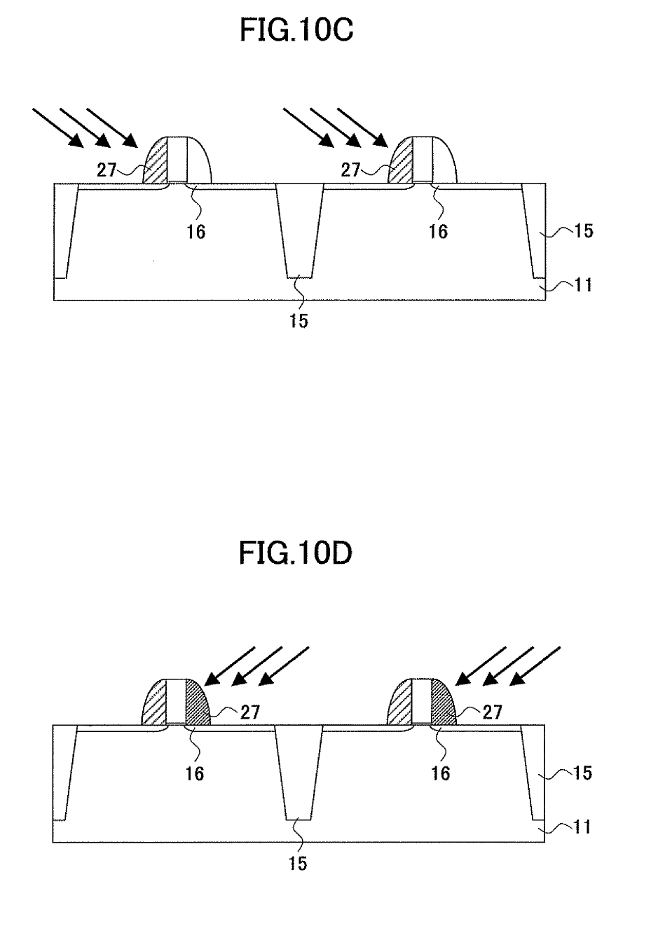

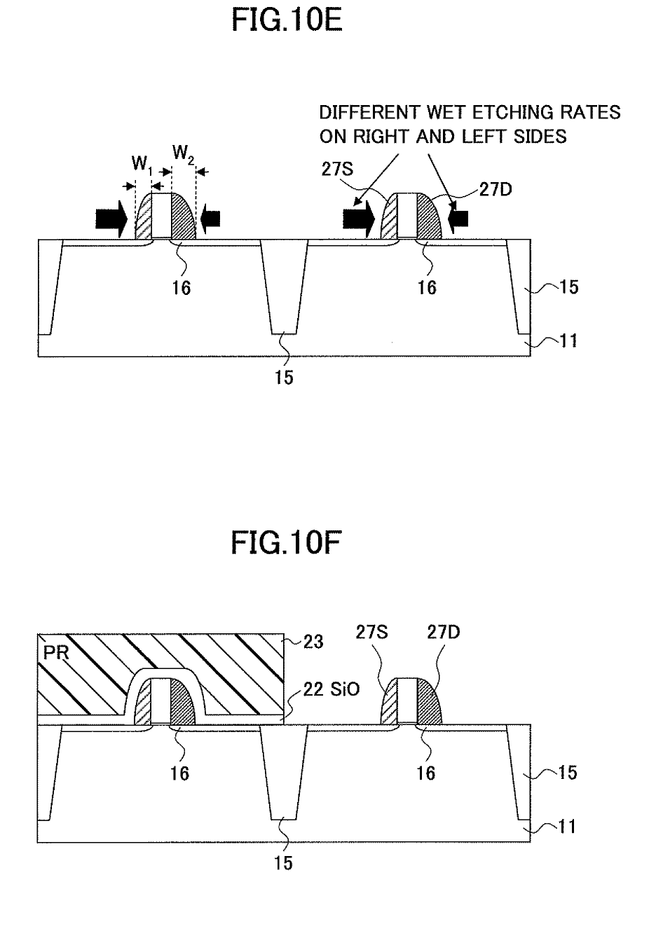

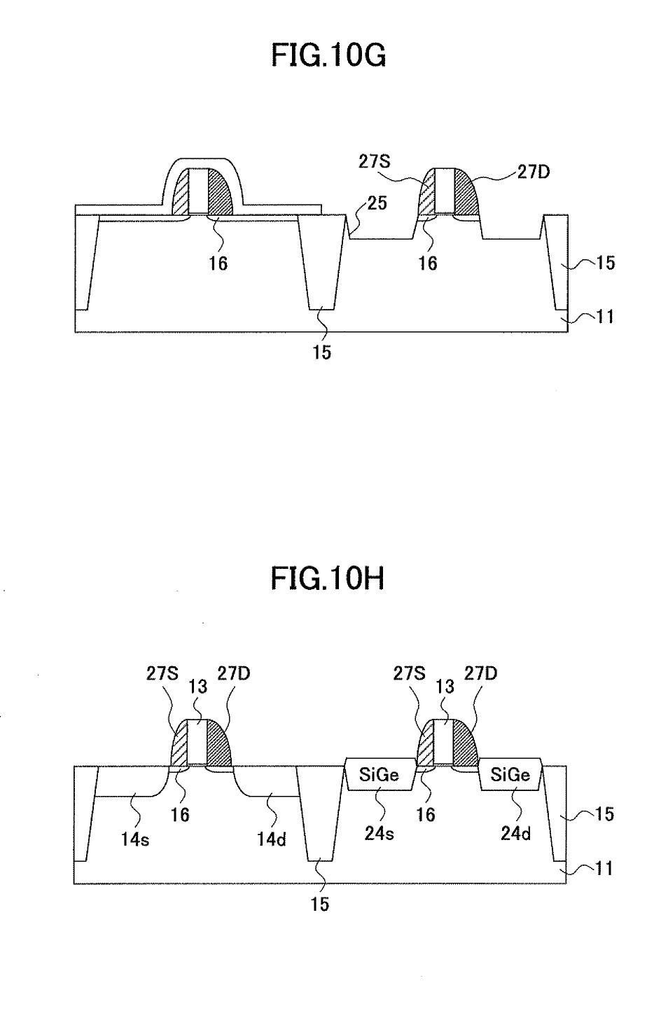

FIGS. 10A through 10H are diagrams illustrating a variation of the semiconductor device manufacturing process of this embodiment. According to this variation, the double sidewall (structure) is replaced with a single sidewall (structure), and the ion kind for causing the wet etching rate to differ between the source side and the drain side and the etchant are also changed.

In the process of FIG. 10A, the same as in the process of FIG. the gate insulating films 12 and the gate electrodes 13 are formed at predetermined positions on the silicon substrate 11 in which the STIs 15, a well (not graphically illustrated), and channels (not graphically illustrated) are formed, and the source and drain extension regions 16 are formed in the NMOS region and the PMOS region by alternately covering the PMOS region and the NMOS region.

As illustrated in FIG. 10B, a silicon oxide (SiO₂) film of approximately 60 nm in thickness is deposited on the structure of FIG. 10A by CVD at a film formation temperature of 600° C. or less, and anisotropic etching is performed, so that single SiO₂ layer sidewalls 27 are formed.

As illustrated in FIG. 10C, Ge⁺ ions are implanted unidirectionally (from the source side) into the source-side sidewalls 27 with a dose of 5E14 cm⁻² at 10 keV at a tilt angle of 30° to 60° (unidirectional tilt implantation of Ge⁺ ions).

Next, as illustrated in FIG. 10D, B⁺ ions are implanted unidirectionally (from the drain side) into the drain-side sidewalls 27 with a dose of 5E14 cm⁻² at 1 keV at a tilt angle of 30° to 60° (unidirectional tilt implantation of B⁺ ions). As a result, the etching rate with respect to hydrofluoric acid (HF) is higher for the drain-side sidewalls 27 than for the source-side sidewalls 27.

It is the same as in the case of the processes of FIGS. 9C and 9D that the etching rate with respect to hydrofluoric acid (HF) may be caused to differ by performing only one of the processes of FIGS. 10C and 10D. Further, it is also the same as in the process of FIG. 9D that the difference in etching rate may be enhanced by performing annealing after implanting ions for promoting and/or slowing down the etching rate. The above-described conditions of implantation energy levels and implantation doses are also determined so as to cause the etching rate with respect to HF to differ effectively.

Next, as illustrated in FIG. 10E, the structure of FIG. 10D is subjected to wet etching with HF to cause the width W₁ of the source-side sidewall 27 to be smaller than the width W₂ of the drain-side sidewall 27 in each of the NMOS region and the PMOS region, so that source-side and drain-side sidewall spacers 27S and 27D are formed.

In the processes in FIGS. 10F, 10G, and 10H, the same as in the processes of FIGS. 9F, 9G, and 9H, the (strain) Si₁₋ₓGeₓ (0<x<0.3) source and drain layers 24s and 24d are formed in the PMOS region, and the deep source and drain regions 14s and 14d are formed in the NMOS region. Thereafter, the compressive CESL 21c and the tensile CESL 21t (FIG. 6) are formed on the protection film 29 (FIG. 6) in the PMOS region and the NMOS region, respectively.

By thus selecting appropriate kinds of ions and an appropriate etchant and performing unidirectional ion implantation at high tilt angle on each of the source side and the drain side, it is possible to form an asymmetrical sidewall spacer structure.

By thus using a strained-Si technology and an asymmetrical sidewall structure, it is possible to improve characteristics efficiently with channel strain and to control a short-channel effect for proper operations also in high-performance logic devices less than or equal to 30 nm in gate length.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiment of the present inventions has been described in detail, it should be understood that various changes, substitutions, and alterations could be made hereto without departing from the spirit and scope of the invention.

What is claimed is:

1. A semiconductor device, comprising:
a gate electrode over a semiconductor substrate;
a channel region provided in the semiconductor substrate below the gate electrode; and
a strain generation layer configured to apply stress to the channel region, the strain generation layer being configured to apply greater stress in absolute value to a source edge of the channel region than to a drain edge of the channel region.

2. The semiconductor device as claimed in claim 1, further comprising:
a first sidewall spacer and a second sidewall spacer formed over a source-side sidewall face and a drain-side sidewall face, respectively, of the gate electrode, the first sidewall spacer having a first width smaller than a second width of the second sidewall spacer.

3. The semiconductor device as claimed in claim 2, wherein at least one of the first sidewall spacer and the second sidewall spacer is implanted with ions to change a wet etching rate with respect to a predetermined etchant.

4. The semiconductor device as claimed in claim 2, wherein the first sidewall spacer is implanted with ions of one of phosphorus and germanium.

5. The semiconductor device as claimed in claim 2, wherein the second sidewall spacer is implanted with ions of boron.

6. The semiconductor device as claimed in claim 2, wherein each of the first sidewall spacer and the second sidewall spacer has a double structure of a silicon oxide film and a silicon nitride film, and
the first sidewall spacer has the silicon nitride film thereof implanted with ions to promote an etching rate with respect to a predetermined etchant, and the second sidewall spacer has the silicon nitride film thereof implanted with ions to slow down an etching rate with respect to the predetermined etchant.

7. The semiconductor device as claimed in claim 2, wherein each of the first sidewall spacer and the second sidewall spacer has a double structure of a silicon oxide film and a silicon nitride film, and
the first sidewall spacer has the silicon nitride film thereof implanted with ions to promote an etching rate with respect to a predetermined etchant, or the second sidewall spacer has the silicon nitride film thereof implanted with ions to slow down an etching rate with respect to the predetermined etchant.

8. The semiconductor device as claimed in claim 1, wherein the strain generation layer is a contact etching stop layer positioned above the gate electrode.

9. The semiconductor device as claimed in claim 1, wherein the strain generation layer is a compound semiconductor layer embedded in a source region and a drain region of the semiconductor substrate.

10. The semiconductor device as claimed in claim 1, further comprising:
an NMOS region and a PMOS region,
wherein the strain generation layer is configured to apply tensile stress to the NMOS region and compressive stress to the PMOS region.

11. A method of manufacturing a semiconductor device, comprising:
forming a gate electrode on a semiconductor substrate;
forming a first sidewall spacer and a second sidewall spacer on a first side and a second side, respectively, of the gate electrode;
implanting an impurity into one of the first sidewall spacer and the second sidewall spacer so as to cause a wet etching rate to differ between the first and second sidewall spacers; and
etching the first sidewall spacer and the second sidewall spacer after said implanting.

12. The method as claimed in claim 11, wherein the impurity is implanted from a single direction at a predetermined tilt angle in said implanting.

13. The method as claimed in claim 11, wherein said etching is wet etching.

14. The method as claimed in claim 11, wherein:
each of the first sidewall spacer and the second sidewall spacer is formed to have a double structure of a silicon oxide film and a silicon nitride film in said forming the first sidewall spacer and the second sidewall spacer,
phosphorus is implanted into the one of the first sidewall spacer and the second sidewall spacer from a single direction in said implanting, and
the one of the first sidewall spacer and the second sidewall spacer implanted with the phosphorus is subjected to wet etching with phosphoric acid in said etching.

15. The method as claimed in claim 11, wherein:
the first sidewall spacer and the second sidewall spacer are formed of a silicon oxide film in said forming the first sidewall spacer and the second sidewall spacer,
germanium is implanted into the one of the first sidewall spacer and the second sidewall spacer from a single direction in said implanting, and
the one of the first sidewall spacer and the second sidewall spacer implanted with the germanium is subjected to wet etching with hydrofluoric acid in said etching.

16. The method as claimed in claim 11, wherein boron is implanted into the one of the first sidewall spacer and the second sidewall spacer from a single direction to slow down the wet etching rate with respect to one of phosphoric acid and hydrofluoric acid in said implanting.

17. The method as claimed in claim 11, wherein the impurity is implanted into the one of the first sidewall spacer and the second sidewall spacer from a single direction at a tilt angle of 30° to 60° relative to the gate electrode in said implanting.

18. The method as claimed in claim 11, further comprising:
forming a strain generation layer configured to apply stress to a region in the semiconductor substrate below the gate electrode after said forming the first sidewall spacer and the second sidewall spacer.

19. The method as claimed in claim 18, further comprising:
forming a contact etching stop layer above the gate electrode as the strain generation layer in said forming the strain generation layer.

20. The method as claimed in claim 18, further comprising:
forming a strain source layer and a strain drain layer as the strain generation layer in a source region and a drain region on a first side and a second side, respectively, of the gate electrode in said forming the strain generation layer.
